(19) United States
(12) Patent Application Publication
(10) Pub. No.: US 2011/0109000 A1
(43) Pub. Date: May 12, 2011

(54) SEMICONDUCTOR PACKAGE AND METHOD OF FORMING THE SAME

(76) Inventors: Sang-Uk Kim, Cheonan-si (KR); Hyo-Chang Ryu, Seo-gu (KR); Jin-Woo Park, Seoul (KR); Dae-young Choi, Yeosu-si (KR); Mi-yeon Kim, Asan-si (KR)

(21) Appl. No.: 12/899,859

(22) Filed: Oct. 7, 2010

(30) Foreign Application Priority Data
Nov. 6, 2009 (KR) 10-2009-0107119

(51) Int. Cl. H01L 23/28

(52) U.S. Cl. 257/787; 257/E23.116

(57) ABSTRACT

Provided are a semiconductor package and a method of forming the same. The semiconductor package includes a stress reliever disposed on a part (more specifically, a weak part) of a semiconductor chip. The stress reliever relieves thermal and/or physical stresses caused by a molding layer. As a result, the semiconductor chip does not suffer from the thermal and/or physical stresses.

### CROSS-REFERENCE TO RELATED APPLICATIONS

This U.S. non-provisional patent application claims priority under 35 U.S.C. §119 to Korean Patent Application No. 10-2009-0107119, filed on Nov. 6, 2009, the entire contents of which are hereby incorporated by reference.

### BACKGROUND

The inventive concepts relate to semiconductor packages and methods of forming the same.

With the advance in the electronic industry, demands for higher performance, higher speed and miniaturization for new products are increasing. In response to these trends, semiconductor mounting technologies are increasingly adopting packaging methods to mount a plurality of semiconductor chips on a semiconductor substrate or stack a package on another package. Such technologies include a molding process to protect mounted semiconductor chips from outside moisture or contamination. The molding process can be carried out by putting a substrate with a mounted semiconductor chip, in a mold and supplying a thermosetting plastic resin liquid.

### SUMMARY

Embodiments of the inventive concept may provide a semiconductor package and a method of forming the same.

According to exemplary embodiments of the inventive concept, the semiconductor package may comprise a semiconductor chip; at least one stress reliever disposed on the semiconductor chip; and a molding layer disposed to cover a side surface of the stress reliever and at least a portion of the semiconductor chip while partially exposing the stress reliever.

In some embodiments, the semiconductor chip may comprise a weak part and the stress reliever is disposed to overlap the weak part.

In some embodiments, the weak part may comprise a cell sensitive to heat or pressure. More specifically, the weak part may comprise at least one selected from the group consisting of a digital-to-analog converter (DAC) cell, an analog-to-digital converter (ADC) cell and a fuse box.

In some embodiments, a portion of the stress reliever may protrude outward from the upper surface of the molding layer.

In some embodiments, the semiconductor package may further comprise an adhesive layer interposed between the semiconductor chip and the stress reliever.

In some embodiments, the stress reliever may have at least two different widths. More specifically, the stress reliever may have a first width proximal to the semiconductor chip and a second width proximal to the surface of the molding layer. The first width may be greater than the second width.

In some embodiments, the stress reliever may have a smaller elastic (or Young's) modulus than the molding layer.

In some embodiments, the stress reliever may have a lower thermal conductivity than that of the molding layer.

In some embodiments, the stress reliever may comprise a rubber.

According to one embodiment of the inventive concept, the method may comprise mounting a semiconductor chip on a substrate, disposing a stress reliever on a portion of the semiconductor chip; and forming a molding layer to cover the semiconductor chip and a side surface of the stress reliever while partially exposing the stress reliever.

The semiconductor chip according to the present embodiment may comprise a weak part and the stress reliever is disposed to overlap the weak part.

According to an embodiment of the present inventive concept, disposing a stress reliever may further comprise attaching an adhesive layer to a surface of the stress reliever adjacent to the semiconductor chip.

In some embodiments, forming a molding layer may comprise loading the substrate upon which the stress reliever is disposed on a lower mold; disposing an upper mold onto the stress reliever; supplying a thermosetting plastic resin liquid to cover the side surface of the stress reliever, the semiconductor chip and the substrate; and forming the molding layer by curing the thermosetting plastic resin liquid, for example, through a baking process.

In some embodiments, the upper mold may be disposed to adjoin the stress reliever.

In some embodiments, the method may further comprise separating the upper mold from the substrate after performing the curing process. The stress reliever protrudes from the surface of the molding layer when the upper mold is separated from the substrate.

### BRIEF DESCRIPTION OF THE DRAWINGS

The accompanying drawings are included to provide a further understanding of the present inventive concept, and are incorporated in and constitute a part of this specification. The drawings illustrate exemplary embodiments of the present inventive concept and, together with the description, serve to explain principles of the present inventive concept. In the figures:

FIG. 1 is a cross-sectional view of a semiconductor package according to one exemplary embodiment of the present inventive concept.

FIG. 2 is an enlarged view of the portion A in FIG. 1.

FIG. 3 is cross-sectional views of various types of stress relievers in FIG. 1.

FIG. 4 is a flowchart illustrating a method of manufacturing a semiconductor package according to one exemplary embodiment of the present inventive concept.

FIGS. 5 through 10 are cross-sectional views illustrating the steps of manufacturing a semiconductor package.

FIG. 11 is a cross-sectional view of a semiconductor package according to another exemplary embodiment of the present inventive concept.

FIG. 12 is a cross-sectional view of a semiconductor package according to still another exemplary embodiment of the present inventive concept.

FIG. 13 is a cross-sectional view of a semiconductor package according to even still another exemplary embodiment of the present inventive concept.

FIG. 14 illustrates an exemplary package module containing a semiconductor package according to the present inventive concept.

FIG. 15 illustrates an exemplary electronic device containing a semiconductor package according to exemplary embodiments of the present inventive concept.

FIG. 16 is a block diagram of a memory system containing a semiconductor package according to exemplary embodiments of the present inventive concept.

### DETAILED DESCRIPTION

Preferred embodiments of the present inventive concept will be described below in more detail with reference to the accompanying drawings. The embodiments of the present inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

In the drawings, the sizes and relative sizes of layers and regions are exaggerated for clarity. It will be understood that when an element such as a layer, region or substrate is referred to as being “on” another element, it can be directly on the other element or intervening elements may also be present. Like numerals refer to like elements throughout.

### Example Embodiment 1

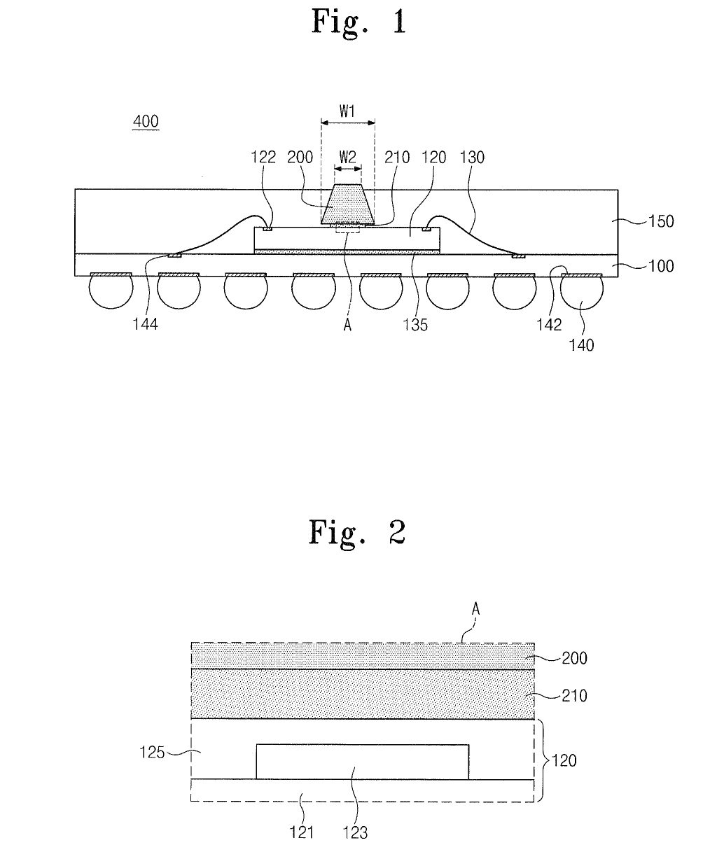

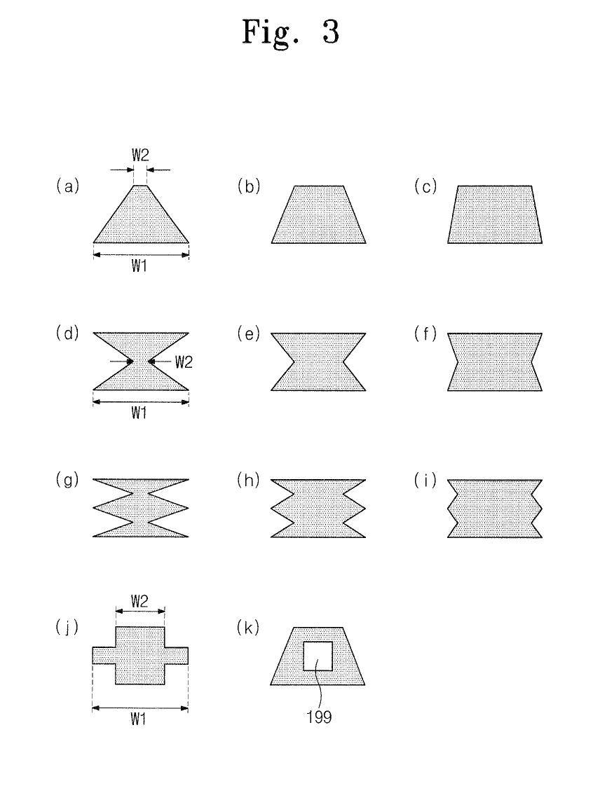

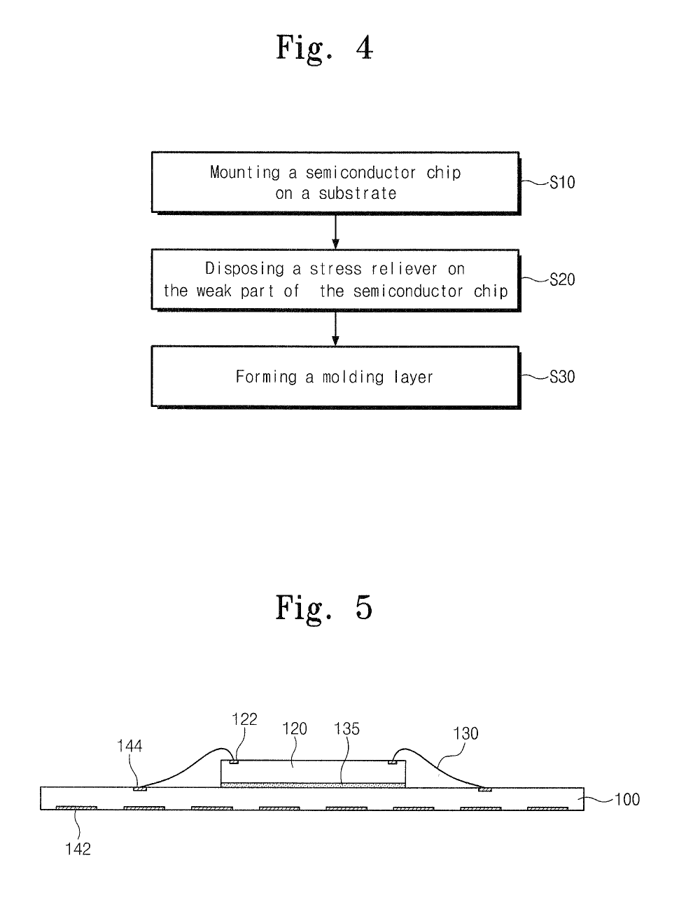

FIG. 1 is a cross-sectional view of a semiconductor package according to one exemplary embodiment of the inventive concept. FIG. 2 is an enlarged view of the portion A in FIG. 1. FIG. 3 is a cross-sectional view of various types of stress relievers in FIG. 1.

Referring to FIGS. 1 and 2, a semiconductor package 400 according to the present embodiment may comprise a substrate 100. First connection terminals 144 may be disposed on the upper surface of the substrate 100, and second connection terminals 142 may be disposed on the lower surface thereof. Conductive balls such as solder balls 140 may be coupled to the second connection terminals 142. A semiconductor chip 120 containing bond pads or chip terminals 122 may be mounted on the substrate 100. In the present embodiment, the semiconductor chip 120 may be attached to the substrate 100 by, for example, an adhesive 135 and the chip terminals 122 may be connected to the first connection terminals 144 such as by wires 130. However, the present invention is not limited to such features. For example, the semiconductor chip 120 may be attached to the substrate 100 via a die attach paste. The chip terminals 122 may be connected to the first connection terminals 144 without using the wires 130. For example, the semiconductor chip 120 may be mounted by a flip-chip bonding method. A stress reliever 200 may be disposed on at least a portion of the semiconductor chip 120. An adhesive layer 210 may be interposed between the stress reliever 200 and the semiconductor chip 120. The semiconductor chip 120 may comprise a semiconductor substrate 121, a weak part 123, and a passivation layer 125 covering the semiconductor substrate 121 and the weak part 123. The weak part 123 may comprise a cell or a portion that is sensitive to heat or pressure. For example, the weak part 123 may comprise at least one selected from the group consisting of a digital- to-analog converter (DAC) cell, an analog-to-digital converter (ADC) cell and a fuse box.

Referring to FIGS. 1 through 3, the stress reliever 200 may be disposed to overlap the weak part 123. The side surface of the stress reliever 200, the semiconductor chip 120 and the semiconductor substrate 100 may be covered with a molding layer 150. The molding layer 150 may not cover, but expose the upper surface of the stress reliever 200. The stress reliever 200 may be formed of a material having a smaller elastic (or Young's) modulus than that of the molding layer 150. In addition or alternatively, the stress reliever 200 may be formed of a material having a lower thermal conductivity than that of the molding layer 150. For example, the stress reliever 200 may be formed of a type of rubber, e.g., a silicon-based rubber. The stress reliever 200 may have various shapes of cross-sections as illustrated in FIG. 3 (a) through (k). The stress reliever 200 may comprise a first width W1 proximal to the semiconductor chip 120 and a second width W2 proximal to the upper surface of the molding layer 150. The first width W1 may be greater than the second width W2. As a result, even when a stress is applied to the stress reliever 200 by the molding layer 150, the stress reliever 200 will not fall out. Moreover, due to the lower thermal conductivity of the stress reliever 200 than that of the molding layer 150, thermal stress applied to the weak part 123 of the semiconductor chip 120 may be relieved. FIG. 3(k) illustrates a stress reliever 200 containing an internal relief portion 199. The internal relief portion 199 may be filled with a gas such as air or non-gaseous materials such as the aforementioned silicon-based rubber. In other words, FIG. 3(k) discloses a stress reliever 200 having a structure of at least double layers.

In addition, because the stress reliever 200 may have an elastic (or Young's) modulus lower than that of the molding layer 150, the stress reliever 200 may absorb and relieve physical stress applied to the weak part 123 of the semiconductor chip 120.

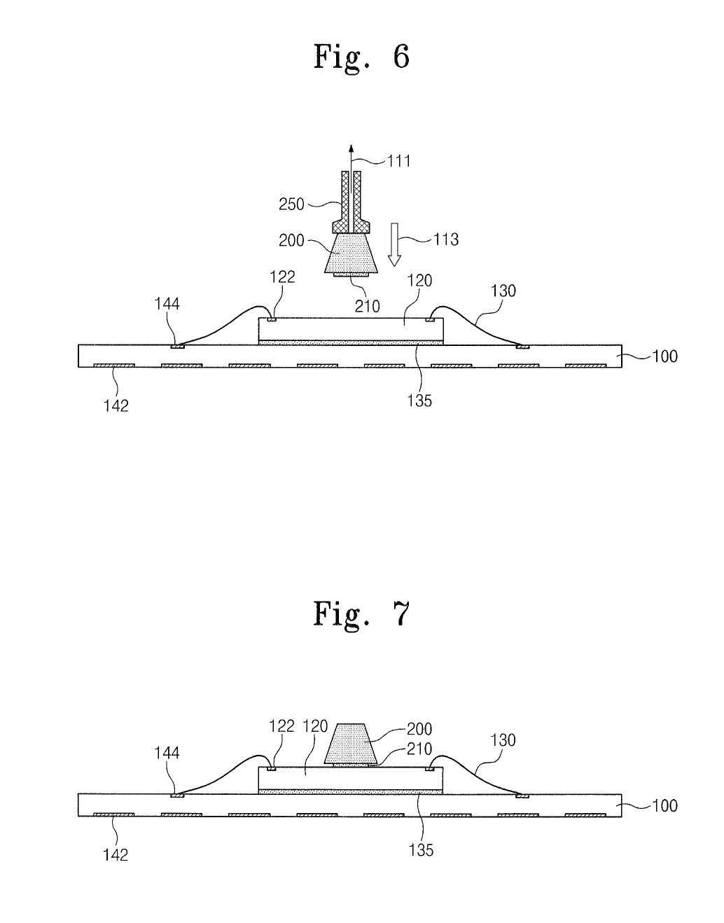

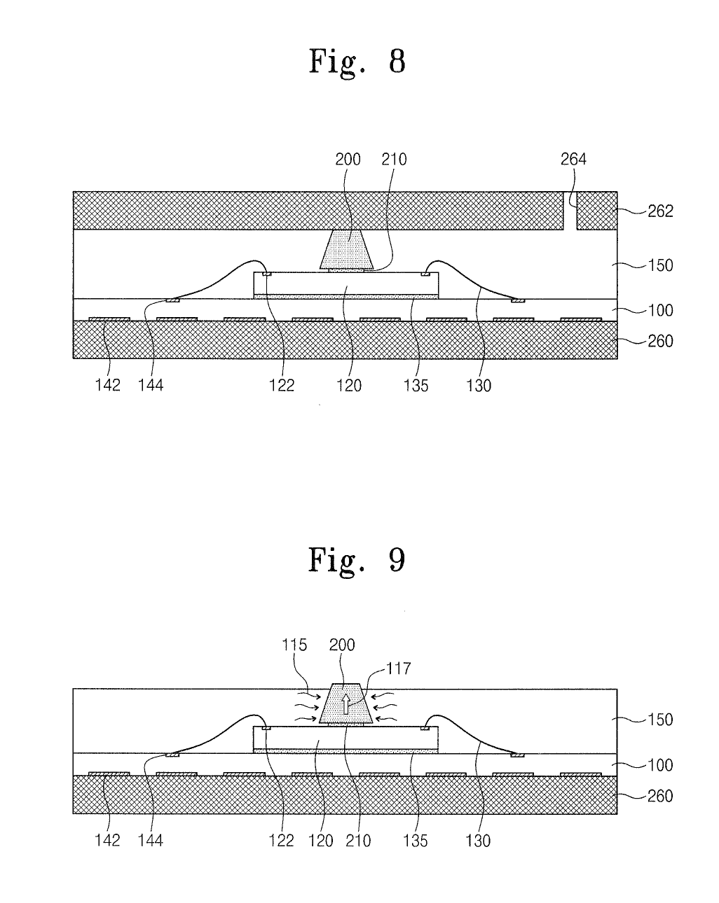

Next, a method of manufacturing the semiconductor package according to the present embodiment will be explained hereinbelow. FIG. 4 is a flowchart illustrating a method of manufacturing a semiconductor package according to the one example embodiment 1. FIGS. 5 through 10 are cross-sectional views illustrating the processing steps of manufacturing a semiconductor package according to some embodiments.

Referring to FIGS. 4 and 5, a semiconductor chip 120 is first mounted on a substrate 100. The semiconductor chip 120 may be attached to the substrate 100 via various methods known to one skilled in the art such as using an adhesive 135. First connection terminals 144 on the substrate 100 and chip terminals 122 on the semiconductor chip 120 may be connected using various connection techniques such as wire bonding using wires 130. The semiconductor chip 120 may also be mounted on the substrate 100 using flip-chip bonding.

Referring to FIGS. 4 and 6, the stress reliever 200 may be disposed on the weak part of the semiconductor chip 120 mounted on the substrate 100 (refer to S20 in FIG. 4). The stress reliever 200 may overlap the weak part of the semiconductor chip 120. To accomplish this, the stress reliever 200 can be attached to the lower part of a moving pipe 250, which provides a vacuum or negative pressure along the direction of arrow 111. The moving pipe 250 may then move the stress reliever 200 downward along the direction of arrow 113 onto the weak part of the semiconductor chip 120. An adhesive layer 210 may be pre-attached to the lower portion of the stress reliever 200. A robot arm may be used for moving or putting the stress reliever 200 in place.

Referring to FIGS. 4 and 7, the stress reliever 200 may be disposed on the weak part by the moving pipe 250 and attached to the semiconductor chip 120 by the adhesive layer 210.

Referring to FIGS. 4 and 8, a molding layer 150 is formed to cover the side surface of the stress reliever 200, the semiconductor chip 120 and the semiconductor substrate 100. The substrate 100 may be positioned within a mold 261 to form the molding layer 150. The mold 261 may comprise a lower mold 260 and an upper mold 262, which mate with each other. The mold may have various shapes. The upper surface of the stress reliever 200 may come in contact with the upper mold 262. In the predetermined region of the upper mold 262, an opening 264 may be provided. The mold may be filled by providing a thermosetting plastic resin liquid for forming the molding layer 150 through the opening 264. The thermosetting plastic resin liquid may be a material from the epoxy molding compound (EMC) resin family. The thermosetting plastic resin liquid may be provided to cover the side surface of the stress reliever 200, the semiconductor chip 120 and the semiconductor substrate 100. If the upper surface of the stress reliever 200 is in contact with the upper mold 262, the upper surface of the stress reliever 200 remains uncovered with the resin liquid. Alternatively, if the upper surface of the stress reliever 200 is not in contact with the upper mold 262, an adequate amount of the resin liquid is provided so as not to cover the upper surface of the stress reliever 200.

The molding layer 150 may be formed by curing the resin liquid through, for example, a subsequent baking process. During the curing process, the stress reliever 200 may relieve the thermal and physical stresses applied by the process to the weak part of the semiconductor chip 120. The molding layer 150 may be provided to cover the side surface of the stress reliever 200, the semiconductor chip 120 and the semiconductor substrate 100.

Referring to FIGS. 4 and 9, the substrate 100 may be separated from the mold 261. Due to the pressure change which occurs when the upper mold 262 is separated from the substrate 100, stress may be induced in the molding layer 150. Although the stress may be applied to the stress reliever 200 in the direction of a solid arrow 115, it may not be delivered to the weak part of the semiconductor chip due to the lower elastic (or Young's) modulus of the stress reliever 200. In addition, because the uncovered upper portion of the stress reliever 200 is exposed to the exterior, the upper portion of the stress reliever 200 may protrude upward from the upper surface of the molding layer 150 due to stress applied to the stress reliever 200. The stress may be released upwardly along a hollow arrow 117. Due to the viscosity and elasticity of the stress reliever 200, the molding layer 150 may absorb the stress to fix the stress reliever 200 in a modified form. In other words, the stress reliever 200 may be fixed while an upper portion of the stress reliever 200 protrudes toward the upper surface of the molding layer 150. In this case, process equipment handling the semiconductor package 400 may be configured to mate with the profile of the upper surface of the protruded stress reliever 200, at a point where it is in contact with the protruded upper surface of the stress reliever 200. In other words, the process equipment handling the semiconductor package 400 according to the present inventive concept may have a concave or convex shaped portion at a point where it is in contact with the protruded upper surface of the stress reliever 200.

Referring to FIG. 10, solder balls 140 may be attached to the lower portion of the second connection terminals 142 in a subsequent process. When attaching the solder balls 140, heat treatment may also be carried out. The stress reliever 200 may also relieve thermal and physical stresses generated during the heat treatment. Accordingly, the semiconductor package 400 according to the present embodiment may be obtained.

### Example Embodiment 2

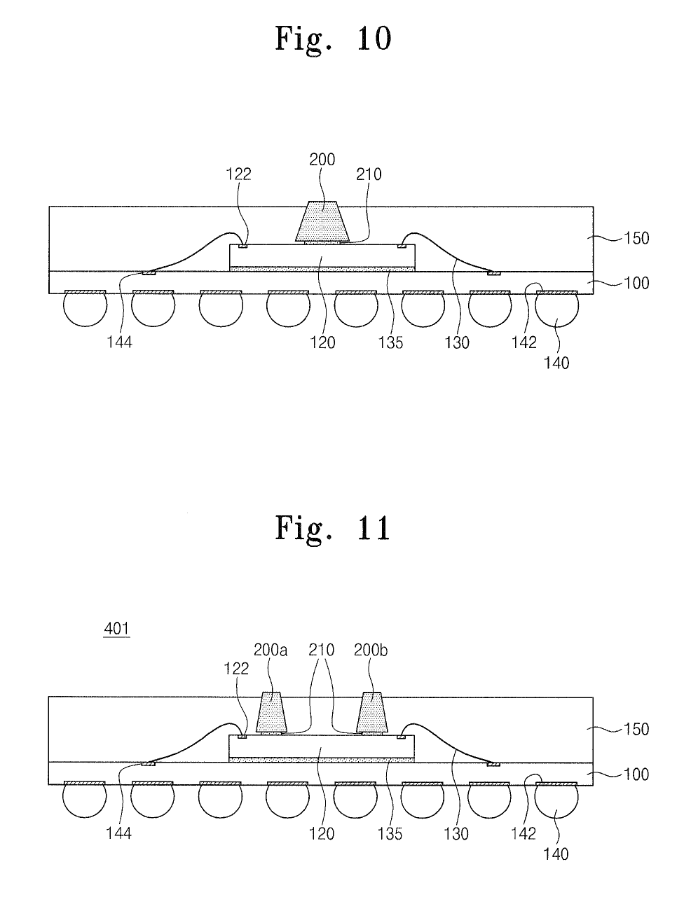

FIG. 11 is a cross-sectional view of a semiconductor package according to another exemplary embodiment of the inventive concept.

Referring to FIG. 11, where the semiconductor package includes two weak parts, a semiconductor package 401 may comprise two stress relievers 200a and 200b. The number and shape of the stress relievers 200a and 200b may vary with the number and locations of the weak parts. In other words, if the weak part exists in a ring shape within the edge of the semiconductor chip 120, the stress relievers 200a and 200b may be disposed in a ring shape to overlap the weak part. Configurations unexplained herein may be the same as disclosed in the example embodiment 1.

### Example Embodiment 3

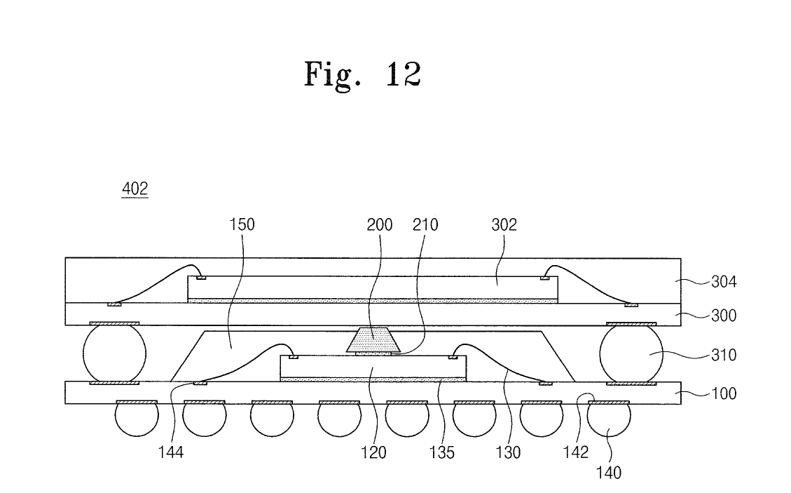

FIG. 12 is a cross-sectional view of a semiconductor package according to still another exemplary embodiment of the inventive concept.

Referring to FIG. 12, a semiconductor package 402 illustrates a case where an additional semiconductor package 401 is stacked on the semiconductor package 400 having the stress reliever 200 as in the example embodiment 1. More specifically, in the semiconductor package 402, a first semiconductor chip 120 may be mounted on a first substrate 100. The stress reliever 200 may be disposed to overlap the weak part of the first semiconductor chip 120 and a first molding layer 150 may be disposed to cover the side surface of the stress reliever 200, the first semiconductor chip 120 and the first substrate 100. A second substrate 300 may be disposed over the first substrate 100. A second semiconductor chip 302 may be mounted on the second substrate 300. The second semiconductor chip may be, for example, a memory chip. The second semiconductor chip 302 and the second substrate 300 may be covered with a second molding layer 304. The second substrate 300 and the first substrate 100 may be electrically connected with each other by, for example, internal support solder balls 310. However, other connection techniques can be used to electrically connect the first semiconductor chip 120 with the second semiconductor chip 302. For example, conductive posts instead of solder balls may be used, or any other suitable methods known to one skilled in the art can be employed. In this semiconductor package 402, the second substrate 300 may be separated from the upper surface of the stress reliever 200. As a result, the upper surface of the stress reliever 200 may not be pressed down by the second substrate 300, and therefore, stresses may not be applied to the weak part. Configurations unexplained herein may be the same as disclosed in the example embodiment 1.

Although not explained in the example embodiments 1 through 3, if a semiconductor chip is mounted on the back surface of a substrate, and a molding layer is formed on the back surface of the substrate, a stress reliever may also be disposed on the back surface of a substrate. In this situation, the lower surface of the stress reliever may be exposed while not being covered with the molding layer.

### Example Embodiment 4

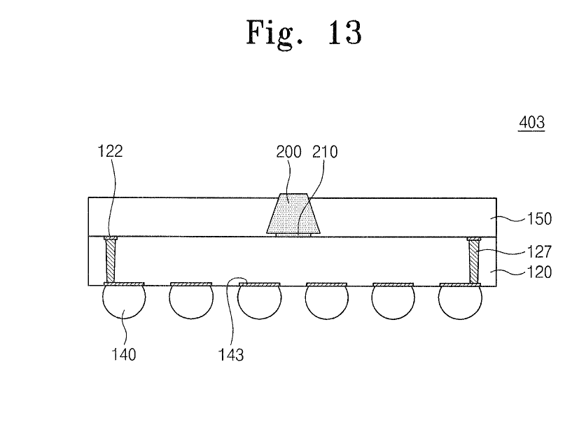

FIG. 13 is a cross-sectional view of a semiconductor package according to yet another exemplary embodiment of the present inventive concept.

Referring to FIG. 13, a semiconductor package 403 is a type of a chip-scale package, and therefore, does not contain the substrate 100 as disclosed in the example embodiments 1 through 3. A stress reliever 200 may be disposed on a semiconductor chip 120, and the upper surface of the semiconductor chip 120 and the side surface of the stress reliever 200 may be covered with a molding layer 150. The semiconductor chip 120 may contain a through via 127, which is connected to chip terminals 122 penetrating the interior of the semiconductor chip 120. Redistribution pads 143 electrically connected to the through via 127 may be disposed on the lower surface of the semiconductor chip 120. External connection terminals such as solder balls 140 may be attached to the redistribution pads 143.

The aforementioned semiconductor packaging technologies may be applied to various types of semiconductor devices and package modules incorporating them.

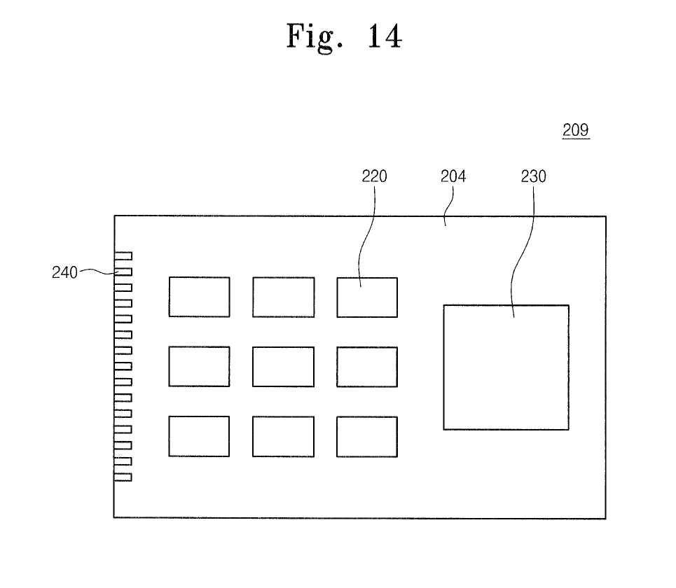

FIG. 14 illustrates an exemplary package module containing a semiconductor package according to example embodiments of the inventive concept. Referring to FIG. 14, a package module 209 may be provided with a semiconductor integrated circuit chip 220 and a semiconductor integrated circuit chip (not illustrated) packaged with quad flat package (QFP) 230. By way of placing the semiconductor integrated circuit chip 220 and semiconductor integrated circuit chip packaged with QFP 230 adopting the semiconductor packaging technologies according to some embodiments of the inventive concept, the package module 209 may be formed. The package module 209 may be connected to external electronic devices through external connection terminals 240 provided on one side of a substrate 204.

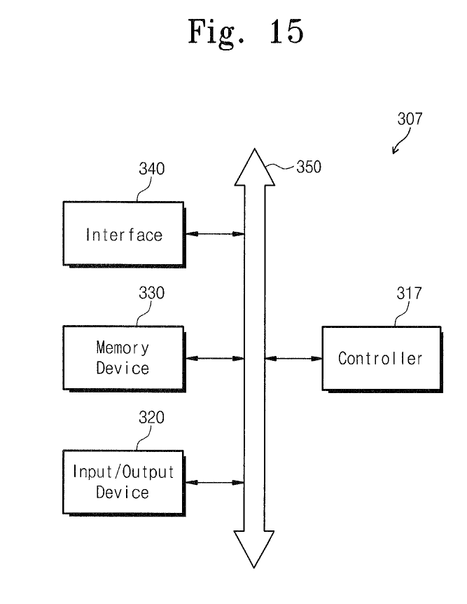

The aforementioned semiconductor packaging technologies may be applied to electronic systems. FIG. 15 illustrates exemplary electronic equipment containing a semiconductor device according to exemplary embodiments of the present inventive concept. Referring to FIG. 15, an electronic system 307 may comprise a controller 317, an input/output device 320 and a memory device 330. The controller 317, the input/output device 320 and the memory device 330 may be connected with each other through, for example, a bus 350. The bus 350 may function as a passageway along which data are transferred. For example, the controller may comprise at least one selected from the group consisting of at least one microprocessor, a digital signal processor, at least one microcontroller, and at least one logic device performing similar functions. The controller 317 and the memory device 330 may comprise a semiconductor package according to the present inventive concept. The input/output device 320 may comprise at least one selected from the group consisting of a keypad, a keyboard, and a displace device. The memory device 330 is a device to store data. The memory device 330 may store data and/or instructions executed by the controller 317. The memory device 330 may comprise a volatile memory device and/or non-volatile memory device. In other words, the memory device 330 may include a flash memory. For example, a flash memory packaged according to the present inventive concept may be mounted on data processing systems such as mobile devices or desktop computers. Flash memories may be used to form a solid-state disk (SSD). In this case, the electronic system 307 may stably store large amount of data in the flash memory system. The electronic system 307 may further comprise an interface 340 to send/receive data to/from communication network. The interface 340 may be a wired or wireless type. For example, the interface 340 may contain an antenna or a wired/wireless transceiver. Although not illustrated herein, those who are skilled in the art will readily appreciate the electronic system 307 may further comprise an application chipset, a camera image processor such as a CMOS image sensor (CIS), and a input/output device.

The electronic system 307 may be implemented in the form of mobile systems, personal computers, industrial computers, or logic systems performing various functions. For example, the mobile system may be one of a personal digital assistant (PDA), a portable computer, a web tablet, a mobile phone, a wireless phone, laptop computer, a memory card, a digital music system and a data transmission and reception system. If the electronic system 307 is a device capable of performing wireless communication, such electronic system 307 may be used according to a communication interface protocol, including third generation communication systems, such as CDMA, GSM, NADC, E-TDMA, WCDMA, and CDMA2000.

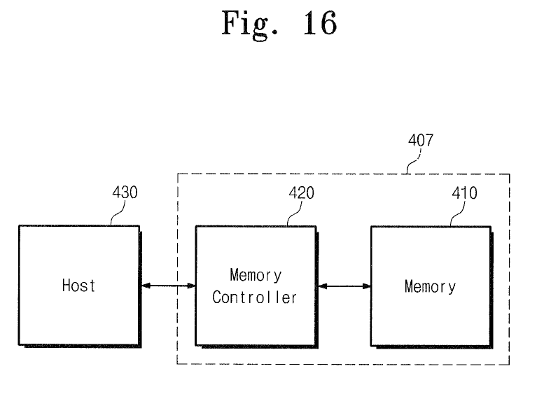

The aforementioned semiconductor device according to the present inventive concept may be provided in the form of a memory card. FIG. 16 is a block diagram of a memory system containing a semiconductor device according to exemplary embodiments of the present inventive concept. Referring to FIG. 16, a memory card 407 may comprise a nonvolatile memory device 410 and a memory controller 420. The nonvolatile memory device 410 and the memory controller 420 may store data or read out stored data. The nonvolatile memory device 410 may comprise at least one nonvolatile memory device packaged according to the inventive concept. The memory controller 420 may, in response to the read/write request of a host, control the flash memory device 410 to read out or store data.

In some other embodiments, a memory controller 420 and the memory 410 may be formed in a single semiconductor device as a system-on-chip (SOC).

According to exemplary embodiments of the present inventive concept, a semiconductor package includes a stress reliever disposed on a part (more specifically, a weak part) of semiconductor chips to reduce thermal and/or physical stresses caused by a molding layer. As a result, the thermal/physical stresses delivered to a semiconductor chip can be relieved.

In addition, before forming the molding layer, a stress reliever is disposed on a semiconductor chip to prevent thermal and/or physical stresses caused by the molding layer from damaging the semiconductor chip.

Reference throughout this specification to “one embodiment” “some embodiments” or “an embodiment” means that a particular feature, structure, or characteristic described in connection with the embodiment is included in at least one embodiment of the present invention. Thus, the appearances of the phrases “in one embodiment,” “some embodiments,” or “in an embodiment” in various places throughout this specification are not necessarily all referring to the same embodiment. Furthermore, the particular features, structures, or characteristics may be combined in any suitable manner in one or more embodiments.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Various operations will be described as multiple discrete steps performed in a manner that is most helpful in understanding the invention. However, the order in which the steps are described does not imply that the operations are order-dependent or that the order that steps are performed must be the order in which the steps are presented.

The foregoing is illustrative of various example embodiments of the present inventive concept. The foregoing merely explains desirable embodiments of the present inventive concept, and it is readily apparent that the inventive concept can have various different combinations and modifications. In other words, the foregoing embodiments of the inventive concept may be modified or corrected within the scope of the inventive concept, the foregoing disclosure and the scope of equivalence, and/or skill and knowledge in the relevant art. The foregoing embodiments have been used to explain the best mode of the present inventive concept, and therefore, reducing to practice by a different form well known in the relevant art and making various modifications in response to the usage and field of specific application of the present inventive concept is possible. Accordingly, the foregoing disclosure of the present inventive concept is not intended to limit the present inventive concept within the scope of disclosed embodiments. The scope of the attached claims should be interpreted to include other possible embodiments.

1. A semiconductor package, comprising:
a semiconductor chip;
at least one stress reliever disposed on the semiconductor chip; and
a molding layer covering the stress reliever and at least a portion of the semiconductor chip while partially exposing the stress reliever.

2. The semiconductor package of claim 1, wherein the semiconductor chip comprises a weak part and the stress reliever overlaps the weak part.

3. The semiconductor package of claim 2, wherein the weak part comprises at least one selected from the group consisting of a digital-to-analog converter (DAC) cell, an analog-to-digital converter (ADC) cell and a fuse box.

4. The semiconductor package of claim 1, wherein a portion of the stress reliever protrudes outward from an upper surface of the molding layer.

5. The semiconductor package of claim 1, further comprising an adhesive layer interposed between the semiconductor chip and the stress reliever.

6. The semiconductor package of claim 1, wherein the stress reliever has at least two different widths.

7. The semiconductor package of claim 6, wherein the stress reliever comprises a first width proximal to the semiconductor chip and a second width proximal to an upper surface of the molding layer, and the first width is greater than the second width.

8. The semiconductor package of claim 1, wherein the stress reliever has an elastic modulus smaller than an elastic modulus of the molding layer.

9. The semiconductor package of claim 1, wherein the stress reliever has a thermal conductivity lower than a thermal conductivity of the molding layer.

10. The semiconductor package of claim 1, wherein the stress reliever comprises a rubber.

11. The semiconductor package of claim 10, wherein the stress reliever comprises a silicon-based rubber.

12. The semiconductor package of claim 1, wherein the semiconductor chip comprises a weak part and the stress reliever has a ring shape overlapping the weak part.

13-18. (canceled)

19. A semiconductor package, comprising:
a semiconductor chip on a package substrate;
a stress reliever disposed on the semiconductor chip; and
an encapsulant encapsulating the stress reliever and at least a portion of the semiconductor chip while partially exposing a top surface of the stress reliever.

20. The semiconductor package of claim 19, wherein the stress reliever has a trapezoidal shape.
